(19) United States
(12) Patent Application Publication
(10) Pub. No.: US 2014/0150952 A1
(43) Pub. Date: Jun. 5, 2014

(54) Lamination Systems With Temperature-Controlled Lamination Rollers

(71) Applicant: Apple Inc., Cupertino, CA (US)

(72) Inventor: Kuo-Hua Sung, Sunnyvale, CA (US)

(73) Assignee: Apple Inc., Cupertino, CA (US)

(21) Appl. No.: 14/048,675

(22) Filed: Oct. 8, 2013

Related U.S. Application Data
(60) Provisional application No. 61/733,365, filed on Dec. 4, 2012.

(51) Int. Cl. H05K 13/00

(52) U.S. Cl. CPC H05K 13/00
USPC 156/64; 156/538; 156/308.2; 156/60

(57) ABSTRACT

A lamination system may be provided for attaching a rigid structure to a compliant structure. The system may include a fixed stage for holding the rigid structure and a movable stage for holding the compliant structure. The rigid structure may be a rigid substrate or an assembly of substrates such as a sensor-on-cover-glass assembly for a touch-sensitive electronic device display. The compliant structure may be a sheet of optically clear adhesive. The system may include a temperature-controlled lamination roller attached to the movable stage. The roller may be heated or cooled during lamination operations. The compliant structure may be laminated onto the rigid structure by pressing the compliant structure onto the rigid structure using the roller while controlling the temperature of the roller. The roller may be heated while pressing the compliant structure onto the rigid structure to minimize the risk of lamination defects.

This application claims priority to U.S. provisional patent application No. 61/733,365 filed Dec. 4, 2012, which is hereby incorporated by reference herein in its entirety.

### BACKGROUND

This relates generally to assembly systems, and more particularly, to lamination systems for electronic devices with displays.

Electronic devices such as portable computers and cellular telephones are often provided with displays. Displays are formed from multiple display layers such as a cover glass layer for protecting the display and internal components, a touch screen panel for gathering touch input from a user, and a stack of liquid crystal display (LCD) structures that generate display images. The display layers are commonly laminated together using adhesive.

If care is not taken, defects such as air bubbles can sometimes form in the display during lamination operations. Defects of this type can negatively affect the visual performance and robustness of the display.

It would therefore be desirable to be able to provide improved lamination systems for electronic devices with displays.

### SUMMARY

A system may be provided for laminating together two or more substrates while minimizing defects generated by the lamination process. The substrates to be laminated together may include display layers for a display. The display layers may include a transparent cover layer, a touch-sensitive layer, and a liquid crystal display cell. Adhesive sheets such as sheets of optically clear adhesive can be used to laminate the substrates together. The optically clear adhesive may be an optically clear ultraviolet-light-curable adhesive.

The system may include hard-to-hard lamination equipment for laminating together first and second rigid substrates. The system may include soft-to-hard lamination equipment for laminating a soft material to a rigid substrate. For example, the soft-to-hard lamination equipment may be used to laminate a sheet of optically clear adhesive to a sensor-on-cover-glass (CGS) assembly that includes a glass cover layer and a touch-sensitive layer.

The soft-to-hard lamination equipment may include first and second mounting stages. A rigid substrate such as the CGS assembly may be temporarily attached to the first mounting stage. An adhesive sheet may be placed on the second stage. The second stage may include a roller member mounted to an edge of the second stage that, when the second stage is moved, presses the adhesive sheet onto the substrate that is attached to the first stage.

In order to minimize potential defects such as air bubbles between the rigid substrate and the adhesive, the roller member may be a temperature-controlled lamination roller that includes one or more temperature control elements. The temperature control elements may be attached to or embedded within the roller. The temperature control elements may include heating elements and/or cooling elements. The heated roller may be used to heat the adhesive prior to pressing the adhesive onto the substrate.

Further features of the invention, its nature and various advantages will be more apparent from the accompanying drawings and the following detailed description of the preferred embodiments.

### BRIEF DESCRIPTION OF THE DRAWINGS

FIG. 1 is a perspective view of an illustrative electronic device with a display in accordance with an embodiment of the present invention.

FIG. 2 is a cross-sectional side view of an illustrative display in accordance with an embodiment of the present invention.

FIG. 3 is a cross-sectional side view of illustrative display layers and backlight structures in accordance with an embodiment of the present invention.

FIG. 4 is a diagram of an illustrative assembly system having lamination equipment in accordance with an embodiment of the present invention.

FIG. 5 is a diagram of illustrative soft-to-hard lamination equipment of an assembly system of the type shown in FIG. 4 in accordance with an embodiment of the present invention.

FIG. 6 is a diagram of illustrative soft-to-hard lamination equipment showing how a rigid substrate may be temporarily attached to a fixed mounting stage and a soft substrate may be temporarily attached to a movable mounting stage during assembly operations in accordance with an embodiment of the present invention.

FIG. 7 is a perspective view of a temperature-controlled lamination roller that is attached to a movable mounting stage showing how the roller may press a soft adhesive layer onto a rigid structure in accordance with an embodiment of the present invention.

FIG. 8 is a flow chart of illustrative steps involved laminating a soft structure to a rigid structure using a temperature-controlled lamination roller in accordance with an embodiment of the present invention.

### DETAILED DESCRIPTION

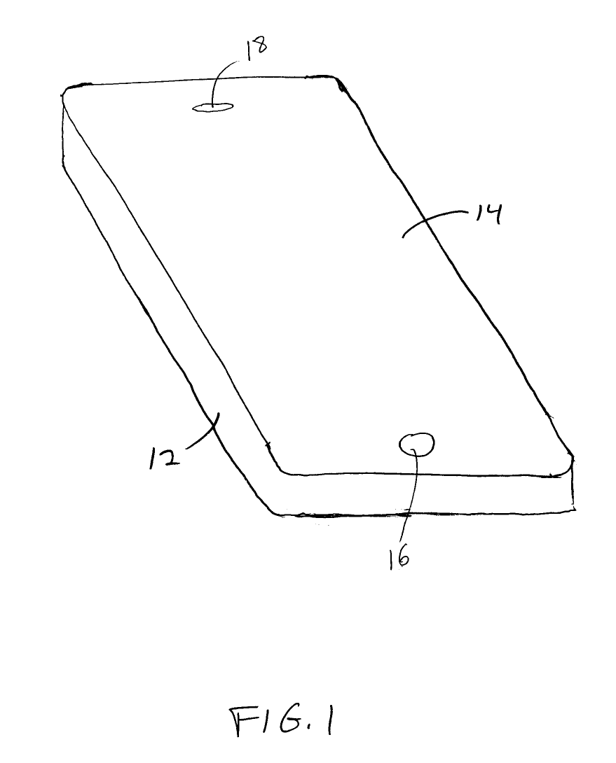

Electronic devices may include displays. The displays may be used to display images to a user. An illustrative electronic device that may be provided with a display is shown in FIG. 1.

As shown in FIG. 1, electronic device 10 may be a handheld device such as a cellular telephone, music player, gaming device, navigation unit, or other compact device. In this type of configuration for device 10, housing 12 may have opposing front and rear surfaces. Display 14 may be mounted on a front face of housing 12. Display 14 may, if desired, have a display cover layer or other exterior layer that includes openings for components such as button 16. Openings may also be formed in a display cover layer or other display layer to accommodate a speaker port such as port 18.

The illustrative configuration for device 10 of FIG. 1 is merely illustrative. In general, electronic device 10 may be a laptop computer, a computer monitor containing an embedded computer, a tablet computer, a cellular telephone, a media player, or other handheld or portable electronic device, a smaller device such as a wrist-watch device, a pendant device, a headphone or earpiece device, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment.

Display 14 may be a touch-sensitive display that includes a touch sensor layer or may be insensitive to touch. Touch sensors for display 14 may be formed from an array of capacitive touch sensor electrodes, a resistive touch array, touch sensor structures based on acoustic touch, optical touch, or force-based touch technologies, or other suitable touch sensor components formed on a touch-sensor substrate.

Displays for device 10 may, in general, include image pixels formed from light-emitting diodes (LEDs), organic LEDs (OLEDs), plasma cells, electrowetting pixels, electrophoretic pixels, liquid crystal display (LCD) components, or other suitable image pixel structures. In some situations, it may be desirable to use LCD components to form display 14, so configurations for display 14 in which display 14 is a liquid crystal display are sometimes described herein as an example. It may also be desirable to provide displays such as display 14 with backlight structures, so configurations for display 14 that include a backlight unit may sometimes be described herein as an example. Other types of display technology may be used in device 10 if desired. The use of liquid crystal display structures and backlight structures in device 10 is merely illustrative.

A display cover layer may cover the surface of display 14 or a display layer such as a color filter layer or other portion of a display may be used as the outermost (or nearly outermost) layer in display 14. A display cover layer or other outer display layer may be formed from a transparent glass sheet, a clear plastic layer, or other transparent member.

Touch sensor components such as an array of capacitive touch sensor electrodes formed from transparent materials such as indium tin oxide may be formed on the underside of a display cover layer, may be formed on a separate display layer such as a glass or polymer touch sensor substrate, or may be integrated into other display layers (e.g., substrate layers such as a thin-film transistor layer).

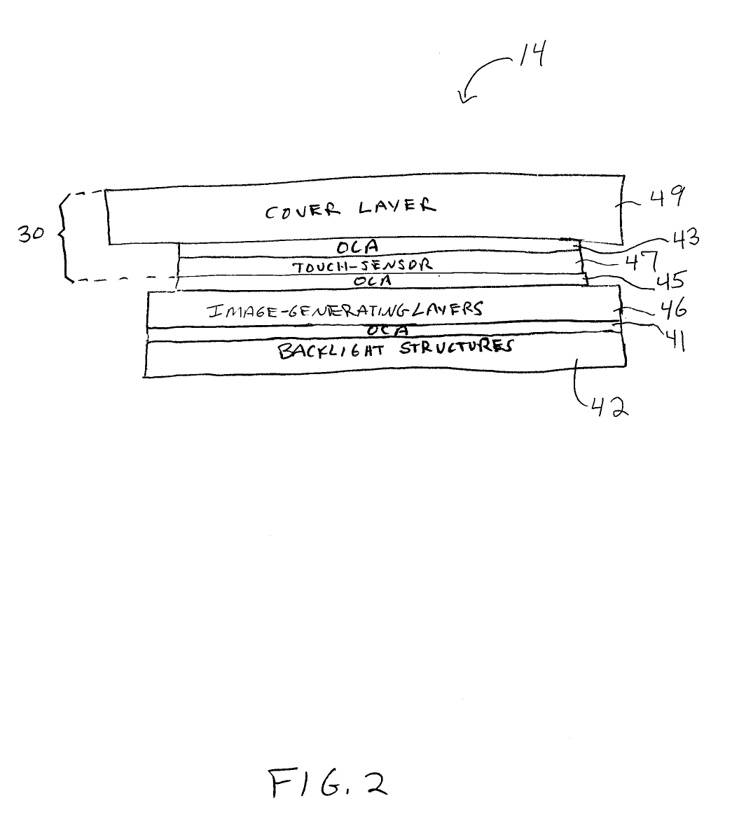

A cross-sectional side view of an illustrative configuration that may be used for display 14 of device 10 is shown in FIG. 2. As shown in FIG. 2, display 14 may include one or more layers of touch-sensitive components such as touch-sensitive layers 47 that are attached to a cover layer such as cover layer 49. Cover layer 49 may be formed from a sheet of rigid or flexible transparent material such as glass or plastic.

Touch-sensitive layers 47 may be attached to cover layer 49 using an adhesive material such as optically clear adhesive (OCA) 43. Optically clear adhesive 43 may be formed from a sheet of compliant light-curable adhesive such as ultraviolet light-curable adhesive, a sheet of pressure-sensitive adhesive or other suitable adhesive material. Touch-sensitive layers 47 may include touch sensor components such as an array of capacitive touch sensor electrodes formed from transparent materials such as indium tin oxide formed on a glass or polymer substrate.

Display 14 may include display layers such as image-generating layers 46 (e.g., a liquid crystal display cell) for generating images to be displayed on display 14. Image-generating layers 46 may include polarizer layers, color filter layers, transistor layers, adhesive layers, layers of liquid crystal material, or other layers for generating display images. Image-generating layers 46 may be attached to touch-sensitive layer 43 using adhesive such as optically clear adhesive 45. Optically clear adhesive 45 may be formed from a sheet of compliant light-curable adhesive such as ultraviolet light-curable adhesive, a sheet of pressure-sensitive adhesive or other suitable adhesive material.

Image-generating layers 46 may use light generated by light-generating structures such as backlight structures 42 to form images to be viewed by a user of device 10. Backlight structures 42 may include light-generating components such as light-emitting diodes, light guiding structures, reflective structures, optical films, etc. Backlight structures 42 may be laminated to image-generating layers 46 using an optically clear adhesive such as optically clear adhesive 41, may be attached to image-generating layers 46 using mechanical attachment members or may be mounted adjacent to layers 46 by attaching backlight structures 42 to one or more structural members in device 10.

During assembly operations for display 14, an assembly system may be used to laminate touch-sensitive layer 47 to cover layer 49 using adhesive layer 43 to form a sensor-on-cover-layer display assembly such as sensor-on-cover-glass (CGS) member 30 (sometimes referred to as a sensor-on-glass assembly, an assembly, or a substrate). The assembly system may then be used to laminate adhesive 45 to touch-sensitive layer 47 prior to attaching image-generating layers 46 to adhesive 45.

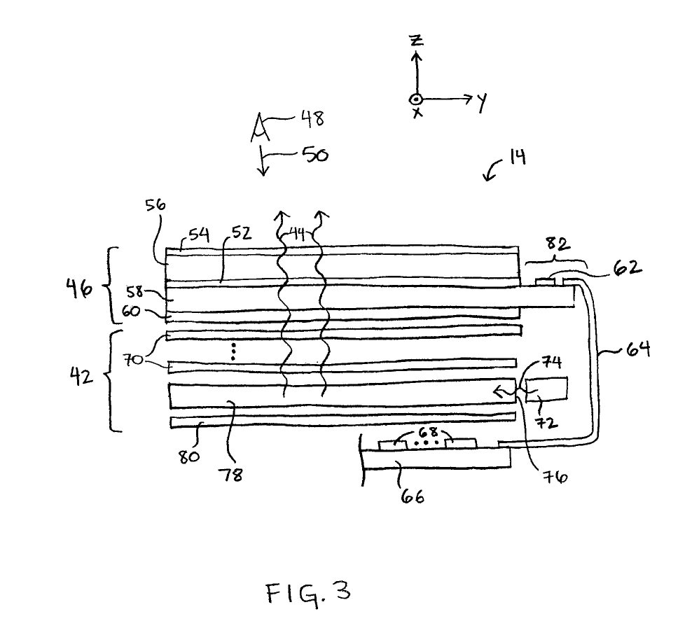

A cross-sectional side view of an illustrative configuration that may be used for image-generating layers 46 and backlight structures 42 of display 14 (e.g., for display layers 46 and backlight structures 42 of the display of FIG. 2, or other suitable display) is shown in FIG. 3. As shown in FIG. 3, display 14 may include backlight structures such as backlight unit 42 for producing backlight 44. During operation, backlight 44 travels outwards (vertically upwards in dimension Z in the orientation of

FIG. 3) and passes through display pixel structures in layers 46. This illuminates any images that are being produced by the display pixels for viewing by a user. For example, backlight 44 may illuminate images on image-generating layers 46 that are being viewed by viewer 48 in direction 50.

Image-generating layers 46 may be mounted in chassis structures such as a plastic chassis structure and/or a metal chassis structure to form a display module such as a liquid crystal display cell for attaching to touch-sensitive layer 47. Layers 46 may form a liquid crystal display or may be used in forming displays of other types.

In a configuration in which layers 46 are used in forming a liquid crystal display, layers 46 may include a liquid crystal layer such a liquid crystal layer 52. Liquid crystal layer 52 may be sandwiched between display layers such as layers 58 and 56. Layers 56 and 58 may be interposed between lower polarizer layer 60 and upper polarizer layer 54. If desired, upper polarizer layer 54 may be attached to an outer cover layer such as cover layer 49 (FIG. 2).

Layers 58 and 56 may be formed from transparent substrate layers such as clear layers of glass or plastic. Layers 56 and 58 may be layers such as a thin-film transistor layer and/or a color filter layer. Conductive traces, color filter elements, transistors, and other circuits and structures may be formed on the substrates of layers 58 and 56 (e.g., to form a thin-film transistor layer and/or a color filter layer). Touch sensor electrodes may also be incorporated into layers such as layers 58 and 56 and/or touch sensor electrodes may be formed on other substrates.

With one illustrative configuration, layer 58 may be a thin-film transistor layer that includes an array of thin-film transistors and associated electrodes (display pixel electrodes) for applying electric fields to liquid crystal layer 52 and thereby displaying images on display 14. Layer 56 may be a color filter layer that includes an array of color filter elements for providing display 14 with the ability to display color images. If desired, layer 58 may be a color filter layer and layer 56 may be a thin-film transistor layer.

In an assembled device, control circuitry such as components 68 on printed circuit 66 may be used to generate information to be displayed on display 14 (e.g., display data). The information to be displayed may be conveyed from circuitry 68 to display driver integrated circuit 62 on a ledge portion 82 of layer 58 using a signal path such as a signal path formed from conductive metal traces in flexible printed circuit 64 (as an example).

Backlight structures 42 may include a backlight light guide plate such as light guide plate 78. Light guide plate 78 may be formed from a transparent material such as clear glass or plastic. During operation of backlight structures 42, a light source such as light source 72 may generate light 74 that is injected into an edge of light guide plate 78. Light source 72 may be, for example, an array of light-emitting diodes.

Light 74 that scatters upwards in direction Z from light guide plate 78 may serve as backlight 44 for display 14. Light 74 that scatters downwards may be reflected back in the upwards direction by reflector 80. Reflector 80 may be formed from a reflective material such as a layer of white plastic or other shiny materials.

To enhance backlight performance for backlight structures 42, backlight structures 42 may include optical films 70. Optical films 70 may include diffuser layers for helping to homogenize backlight 44 and thereby reduce hotspots, compensation films for enhancing off-axis viewing, and brightness enhancement films (also sometimes referred to as turning films) for collimating backlight 44. Optical films 70 may overlap the other structures in backlight unit 42 such as light guide plate 78 and reflector 80. For example, if light guide plate 78 has a rectangular footprint in the X-Y plane of FIG. 3, optical films 70 and reflector 80 may have a matching rectangular footprint.

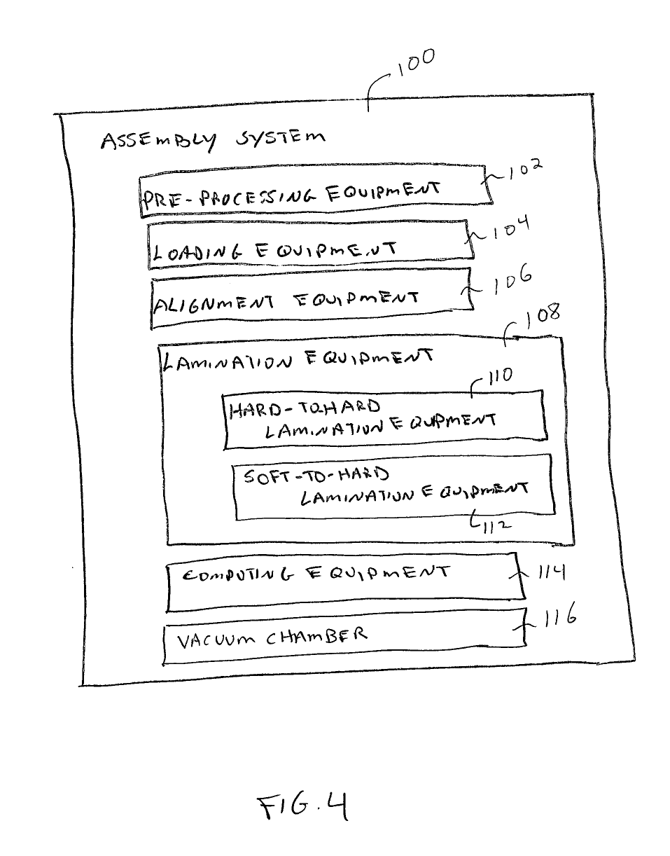

FIG. 4 is a diagram of an illustrative assembly system that may be used for laminating together substrates such as display layers for display 14. During assembly operations for display 14 of device 10, a manufacturing system such as assembly system 100 may be used to assemble image-generating layers 46, cover layer 49, touch sensor 47, and, if desired, backlight unit 42 to form display 14.

As shown in FIG. 4, assembly system 100 may include pre-processing equipment 102. Pre-processing equipment 102 may be used to clean a substrate prior to lamination, remove protective films from a substrate prior to lamination or otherwise pre-process one or more rigid or flexible substrate prior to lamination operations.

System 100 may include lamination equipment 108 such as hard-to-hard lamination equipment 110 and soft-to-hard lamination equipment 112. Hard-to-hard lamination equipment 110 may be used to laminate together two rigid substrates such as image-generating layers 46 and sensor-on-glass assembly 30. Soft-to-hard lamination equipment 112 may be used to attach a soft substrate such as a sheet of optically clear light-curing adhesive onto a rigid substrate such as sensor-on-glass assembly 30. System 100 may include an evacuated portion such as vacuum chamber 116. Some or all of lamination equipment 108 may be formed within vacuum chamber 116 so that the risk of defects such as air bubbles may be further reduced during lamination operations.

System 100 may include other equipment such as loading equipment 104 and alignment equipment 106 for positioning substrates in lamination equipment 108. System 100 may also include computing equipment 114 for controlling lamination equipment 108, loading equipment 104, alignment equipment 106, and pre-processing equipment 102 during lamination operations.

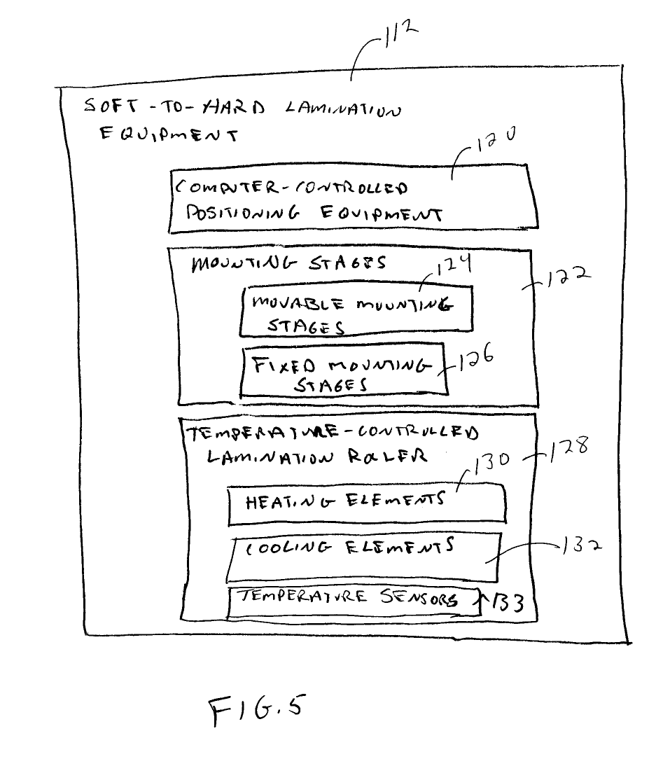

FIG. 5 is a diagram of soft-to-hard lamination equipment 112 of the type that may be used in system such as system 100 of FIG. 4. As shown in FIG. 5, soft-to-hard (STH) lamination equipment 112 may include one or more mounting stages 122. Substrates such as hard substrates (e.g., a sensor-on-glass assembly for an electronic device display) and soft substrates (e.g., sheets of adhesive material) may be mounted on mounting stages 122 during assembly operations for attaching the hard substrate to the soft substrate.

Mounting stages 122 may include movable mounting stages 124 and fixed mounting stages 126. Computer-controlled positioning equipment 120 may be used in moving and positioning movable mounting stages 124 during assembly operations. Computer-controlled positioning equipment 120 may be controlled by computing equipment 114 during assembly operations.

Soft-to-hard lamination equipment 112 may include a lamination roller such as temperature-controlled lamination roller 128. Temperature-controlled lamination roller 128 may be attached to one of mounting stages 122 such as one of movable mounting stages 124. Temperature-controlled lamination roller 128 may include heating elements 130 (e.g., resistive heating elements or other heating elements) cooling elements 132 (e.g., refrigerant lines, thermoelectric coolant structures, or other cooling elements), and/or temperature sensors 133. Heating elements 130 and/or cooling elements 132 may be operated by computing equipment 114 to control the temperature of roller 128 as roller 128 presses a soft substrate onto a rigid substrate. By controlling the temperature of roller 128, the temperature of one or more of the soft substrate and the hard substrate may be modified to minimize defects such as air bubbles between the substrates during assembly operations (e.g., by increasing the compliancy of the soft substrate by heating the soft substrate).

In one suitable situation which is sometimes discussed herein as an example, the temperature of optically clear adhesive 45 may be increased while adhesive 45 is pressed onto sensor-on-glass assembly 30 by heating roller 128 while roller 128 presses adhesive 45 onto sensor-on-glass assembly 30. In this way, the compliancy of adhesive sheet 45 may be increased during lamination operations, thereby reducing the risk of lamination defects in an assembled display such as display 14.

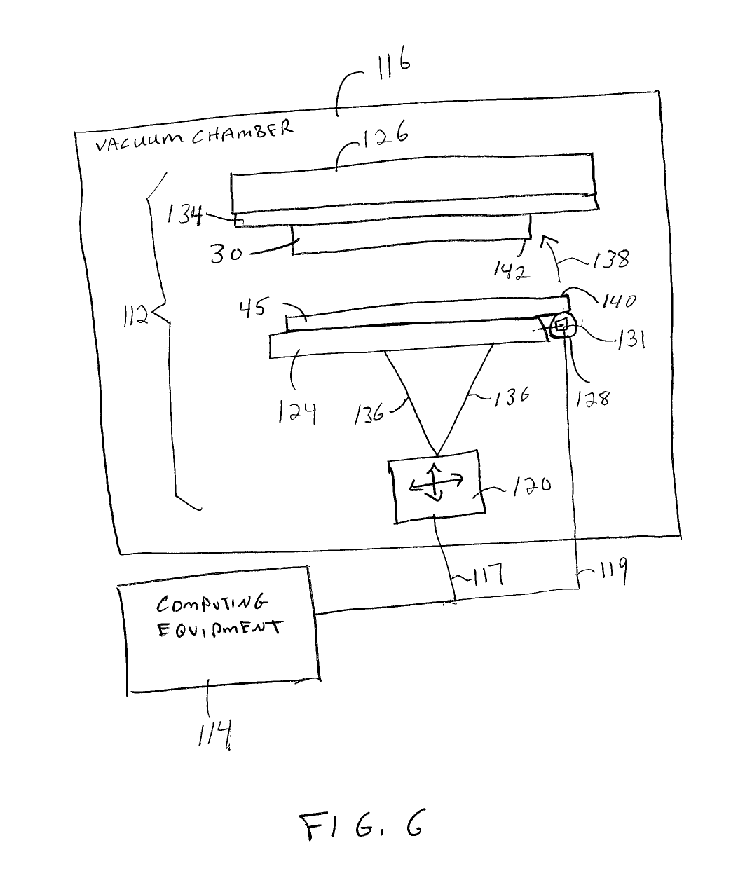

FIG. 6 is a diagram of soft-to-hard lamination equipment 112 inside vacuum chamber 116 during soft-to-hard lamination operations. Vacuum chamber 116 may be formed from an enclosure that has been evacuated of all or nearly all air and other gasses. As shown in FIG. 6, a rigid substrate such as sensor-on-glass assembly 30 may be temporarily attached to fixed mounting stage 126. Stage 126 may include an attachment member such as electrostatic chuck 134 that clamps assembly 30 onto stage 126. Electrostatic chuck 134 (sometimes referred to as an e-chuck) may use electromagnetic fields generated in the chuck to electrostatically hold substrate 30 in a fixed position during lamination operations.

A soft substrate such as adhesive sheet 45 may be temporarily attached to a movable stage such as movable stage 124. Movable state 124 may be rotated, turned, moved laterally or otherwise moved using computer-controlled positioning equipment 120 during lamination operations.

Temperature-controlled lamination roller 128 may be attached to an end of movable stage 124. Temperature control element 131 (e.g., a heating element such as heating element 130, a cooling element such as cooling element 132, and/or a temperature sensor such as temperature sensor 133) may be mounted along an edge of roller 128 as shown in FIG. 6, may be mounted within roller 128, may extend along a surface of roller 128 or may be otherwise positioned on or embedded within roller 128.

Adhesive sheet 45 may be aligned with, and placed upon, stage 124 such that a portion of sheet 45 extends beyond the edge of stage 124 onto roller 128.

During lamination operations, computing equipment 114 may transmit signals over path 117 (e.g., a wired or wireless connection) to computer-controlled positioning equipment 120. Computer-controlled positioning equipment 120 may include one or more motors, levers, pistons such as hydraulic pistons, etc. for moving, rotating, turning, sliding or otherwise positioning stage 124. Computer-controlled positioning equipment 120 may be attached to movable stage 124 using support structures such as structures 136. Signals from computing equipment 114 may instruct equipment 120 to rotate movable stage 124 in direction 138 until edge portion 140 of adhesive sheet 45 contacts edge portion 142 of assembly 30.

During lamination operations, computing equipment 114 may transmit signals over path 119 (e.g., a wired or wireless connection) to temperature control elements such as element 131. Signals from computing equipment 114 may activate or inactivate temperature control elements 131 to selectively heat or cool roller 128. Elements 131 may include a temperature sensor that transmits temperature data associated with the temperature of roller 128 back to computing equipment 114. Computing equipment 114 may modify the operation of heating and/or cooling elements in element 131 to modify the temperature of roller 128 based on the received temperature data.

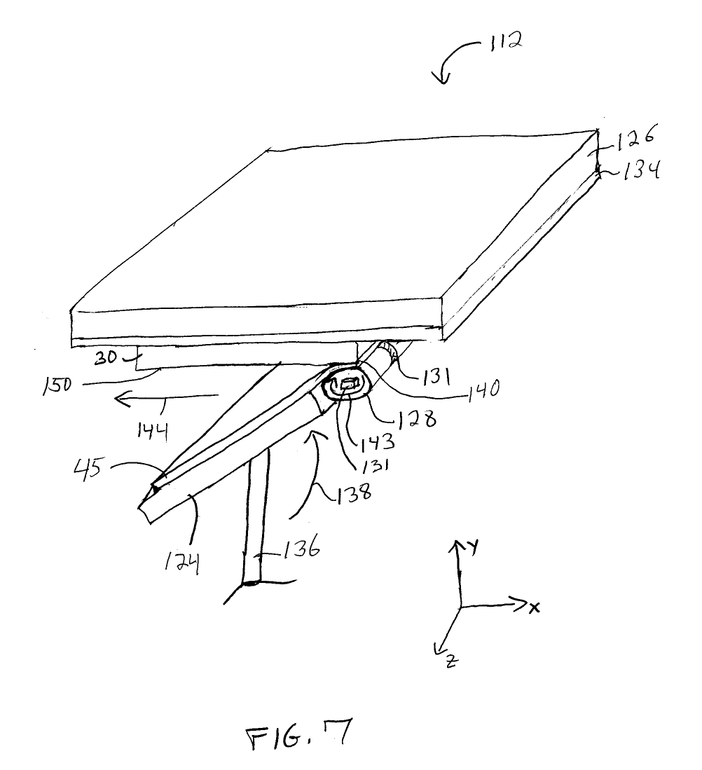

Following rotation of movable stage 124 in direction 138, edge portion 140 of adhesive sheet 45 may be compressed between roller 128 and assembly 30 as shown in the perspective view of equipment 112 in FIG. 7. The temperature of temperature-controlled lamination roller may be set to a desired temperature using temperature control elements 131 prior to compressing edge portion 140 of adhesive sheet 45 between roller 128 and assembly 30 or after compressing edge portion 140 of adhesive sheet 45 between roller 128 and assembly 30.

After setting the temperature of roller 128 to the desired temperature, computing equipment 114 may instruct computer-controlled positioning equipment (see FIG. 6) to move movable stage 124 along direction 144 (i.e., a direction parallel to surface 150 of assembly 30) while asserting pressure on adhesive sheet 45 using roller 128.

As stage 124 is moved in direction 144, roller 128 may rotate in direction 143 thereby rolling adhesive sheet 45 onto surface 150 of assembly 30 while controlling the temperature of adhesive sheet 45 to minimize lamination defects in display 14.

As shown in FIG. 7, temperature control elements 131 (e.g., heating elements, cooling elements, and or temperature sensors) may be formed along an edge of roller 128 and/or may include one or more a strips of temperature control material (e.g., resistive heating material) that wraps around a portion of roller 128. However, this is merely illustrative. As described above, one or more heating elements, one or more cooling elements, and/or one or more temperature sensors may be mounted along an edge of roller 128, may be mounted within roller 128, may extend along a surface of roller 128 or may be otherwise positioned on or within roller 128.

The examples of FIGS. 6 and 7 in which soft-to-hard lamination equipment 112 is used to laminate an adhesive sheet to a sensor-on-glass assembly for an electronic device display are merely illustrative. If desired, soft-to-hard lamination equipment 112 having a temperature-controlled lamination roller may be used to laminate any soft or flexible substrate to any suitable rigid substrate.

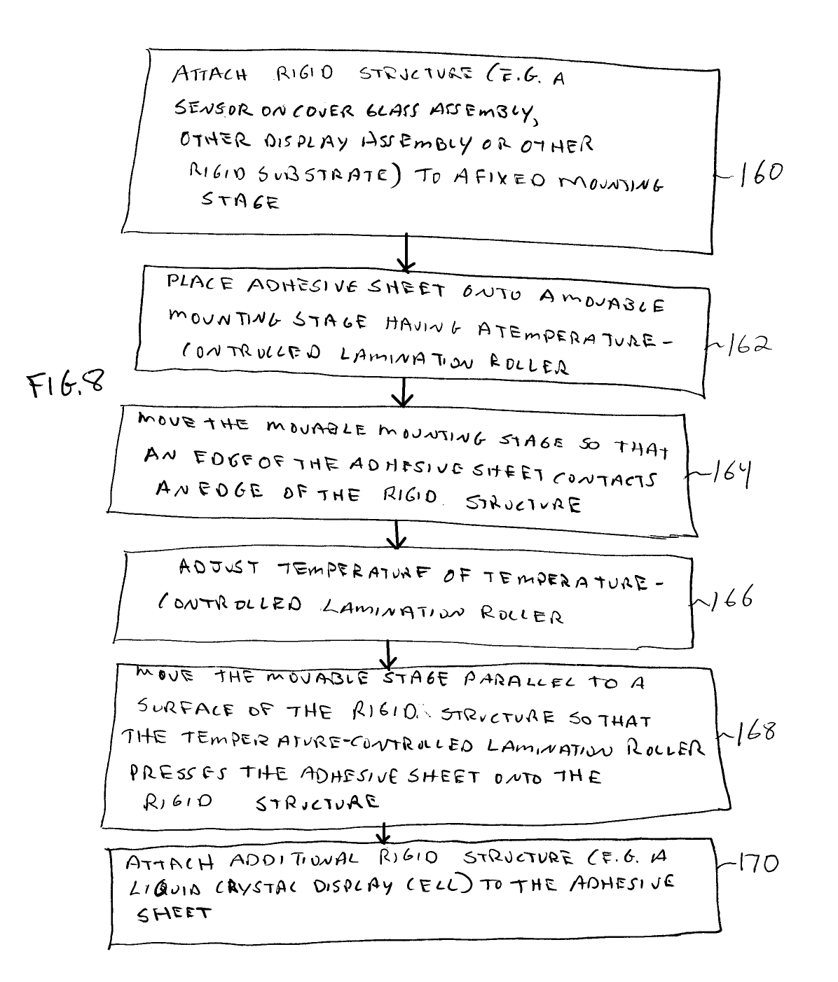

Illustrative steps that may be used to laminate a soft or flexible substrate to a rigid substrate using a temperature-controlled lamination roller of the type shown in FIGS. 5, 6, and 7 are shown in FIG. 8.

At step 160, a rigid structure such as a planar structure, an assembly of substrates or other rigid structures (e.g., a sensor-on-cover-glass assembly or other display assembly or rigid substrate) may be (temporarily) attached to a fixed mounting stage. The fixed mounting stage may include temporary attachment devices such as an electrostatic chuck for attaching the rigid structure to the stage.

At step 162, a flexible substrate such as a sheet of adhesive material (e.g., optically clear light-curable adhesive sheet 45) may be placed on a movable stage having a temperature-controlled lamination roller that is attached along an edge of the movable stage. The flexible substrate may be placed onto the movable stage so that a portion of the flexible substrate at least partially overlaps the roller.

At step 164, the movable mounting stage may be moved so that an edge portion of the flexible substrate (e.g., the adhesive sheet) contacts an edge portion of the rigid structure. When the edge portion of the flexible substrate contacts the edge portion of the rigid structure, the temperature-controlled lamination roller may compress the edge portion of the flexible substrate (e.g., the adhesive sheet) between the roller and the edge portion of the rigid structure.

At step 166, the temperature of the temperature-controlled lamination roller may be adjusted. Adjusting the temperature of the temperature-controlled lamination roller may include heating the roller using one or more heating elements on or within the roller or cooling the roller using one or more cooling elements on or within the roller. Adjusting the temperature of the temperature-controlled lamination roller may include determining the temperature of the temperature-controlled lamination roller using a temperature sensor on or within the roller and adjusting the temperature of the roller based on the determined temperature (e.g., heating the roller if it is determined that the temperature of the roller is unacceptably low or cooling the roller if it is determined that the temperature of the roller is unacceptably high).

At step 168, the movable stage may be moved parallel to a surface of the rigid structure so that the temperature-controlled lamination roller presses the flexible substrate (e.g., the adhesive sheet) onto the surface of the rigid structure. Moving the movable stage parallel to a surface of the rigid structure may include moving the movable stage parallel to a surface of the rigid structure while monitoring and controlling the temperature of the temperature-controlled lamination roller.

At step 170, an additional rigid structure such as an image-generating stack-up for an electronic device display (e.g., a liquid crystal display) may be attached to the adhesive sheet that has been laminated to the rigid structure.

The foregoing is merely illustrative of the principles of this invention and various modifications can be made by those skilled in the art without departing from the scope and spirit of the invention.

What is claimed is:

1. A lamination system for laminating a hard substrate to a soft substrate, the system comprising:
a fixed mounting stage for mounting the hard substrate;
a movable mounting stage for mounting the soft substrate;
a temperature-controlled lamination roller having at least one temperature control element; and
computing equipment coupled to the movable mounting stage and the temperature-controlled lamination roller, wherein the computing equipment is configured to control the temperature of the temperature-controlled lamination roller while moving the movable mounting stage along a direction parallel to a surface of the hard substrate.

2. The lamination system defined in claim 1 wherein the fixed mounting stage for mounting the hard substrate comprises a fixed mounting stage for mounting a display assembly for an electronic device display.

3. The lamination system defined in claim 2 wherein the movable mounting stage for mounting the soft substrate comprises a movable mounting stage for mounting a sheet of adhesive material to be laminated to the display assembly.

4. The lamination system defined in claim 3 wherein the at least one temperature control element comprises a heating element formed on an edge of the temperature-controlled lamination roller.

5. The lamination system defined in claim 3 wherein the at least one temperature control element comprises a heating element embedded within the temperature-controlled lamination roller.

6. The lamination system defined in claim 3 wherein the at least one temperature control element comprises a heating element that includes a strip of heating element material that is wrapped around a portion of the temperature-controlled lamination roller.

7. The lamination system defined in claim 3 wherein the at least one temperature control element comprises a cooling element attached to the temperature-controlled lamination roller.

8. The lamination system defined in claim 3 wherein the at least one temperature control element comprises a heating element and a cooling element.

9. The lamination system defined in claim 8 wherein the at least one temperature control element further comprises a temperature sensor.

10. The lamination system defined in claim 3 wherein the fixed mounting stage comprises an electrostatic chuck that secures the display assembly in a fixed position.

11. A method of laminating a compliant structure to a rigid structure using a soft-to-hard lamination system having a first stage, a second stage, and a temperature-controlled lamination roller attached to an edge of the second stage, the method comprising:
temporarily attaching the rigid structure to the first stage;
temporarily attaching the compliant structure to the second stage;
modifying a temperature of the temperature-controlled lamination roller; and
pressing the compliant structure onto a surface of the rigid structure using the temperature-controlled lamination roller.

12. The method defined in claim 11, further comprising:
before pressing the compliant structure onto the surface of the rigid structure using the temperature-controlled lamination roller, moving the second stage so that an edge portion of the compliant structure contacts an edge portion of the rigid structure.

13. The method defined in claim 12 wherein pressing the compliant structure onto the surface of the rigid structure using the temperature-controlled lamination roller comprises moving the second stage along a direction that is parallel to the surface of the rigid structure.

14. The method defined in claim 11 wherein the temperature-controlled lamination roller comprises a heating element and wherein modifying the temperature of the temperature-controlled lamination roller comprises heating the temperature-controlled lamination roller using the heating element.

15. The method defined in claim 11 wherein the temperature-controlled lamination roller comprises a cooling element and wherein modifying the temperature of the temperature-controlled lamination roller comprises cooling the temperature-controlled lamination roller using the cooling element.

16. The method defined in claim 11 wherein the temperature-controlled lamination roller comprises a temperature sensor, the method further comprising:
while pressing the compliant structure onto the surface of the rigid structure using the temperature-controlled lamination roller, monitoring the temperature of the temperature-controlled lamination roller using the temperature sensor.

17. A method of using a laminating system to attach a liquid crystal display cell to an assembly that includes a glass layer and a touch-sensor substrate attached to the glass layer, the method comprising:
securing the assembly in a fixed position;
placing a sheet of optically clear adhesive material on a movable stage, wherein the movable stage includes a temperature-controlled lamination roller;
heating the temperature-controlled lamination roller; and
laminating the sheet of optically clear adhesive material onto the assembly by pressing the sheet of optically clear adhesive material against the assembly using the heated temperature-controlled lamination roller.

18. The method defined in claim 17, further comprising:
attaching the liquid crystal display cell to the sheet of optically clear adhesive material that has been laminated to the assembly.

19. The method defined in claim 17 wherein pressing the sheet of optically clear adhesive against the assembly using the heated temperature-controlled lamination roller comprises:
compressing an edge portion of the sheet of optically clear adhesive material between the heated temperature-controlled lamination roller and the assembly; and
rolling the heated temperature-controlled lamination roller along a surface of the sheet of optically clear adhesive material.

20. The method defined in claim 19 wherein the temperature-controlled lamination roller comprises an embedded heating element within the temperature-controlled lamination roller and wherein heating the temperature-controlled lamination roller comprises heating the temperature-controlled lamination roller using the embedded heating element.
